(19) United States
(12) Patent Application Publication
(10) Pub. No.: US 2023/0318631 A1
(43) Pub. Date: Oct. 5, 2023

(54) IMPROVING THE PERFORMANCE OF POLAR DECODERS USING VIRTUAL RANDOM CHANNELS

(71) Applicant: CANKAYA UNIVERSITESI, Etimesgut/Ankara (TR)

(72) Inventors: Orhan GAZI, Etimesgut/Ankara (TR); Abdelkareim Abulgaasem A. ALRTAIMI, Etimesgut/Ankara (TR)

(21) Appl. No.: 17/998,292

(22) PCT Filed: Nov. 2, 2021
(86) PCT No.: PCT/TR2021/051114

§ 371 Date: Nov. 9, 2022

(30) Foreign Application Priority Data
Dec. 24, 2020 (TR) 2020/21579

(51) Int. Cl. H03M 13/29; H03M 13/09

(52) U.S. Cl. CPC H03M 13/2927; H03M 13/09

(57) ABSTRACT

In this invention, a novel method for improving the performance of polar decoders using virtual random channels is proposed.

### TECHNICAL FIELD

In this invention, a novel method for improving the performance of polar decoders using virtual random channel is proposed.

### PRIOR ART

The virtual random channels are never used in the decoding of polar codes in the previous studies.

### Aims of the Invention and Brief Description

The present invention is related to improving the performance of polar decoders using virtual random channel in order to bring new advantages to the related technical field.

Advantageous of the proposed method;
1) The structure is suitable for hardware implementations.
2) It improves the performance of polar decoders significantly.

### DEFINITION OF THE FIGURES OF THE INVENTION

The figures have been used in order to further disclose developed improving the performance of polar decoders using virtual random channel by the present invention which the figures have been described below.

FIG. 1 AWGN concatenated with VRC.

FIG. 2 Determination of uₜ for AWGN channel.

FIG. 3 Proposed recursive structure utilizing VRCs for the decoding of polar codes.

FIG. 4 Average iteration number for the decoding of polar code P(128,64) over AWGN Channel.

FIG. 5 FER performance of iterative system for the decoding of polar code P(128,64) over AWGN Channel.

FIG. 6 FER performance of iterative system for the decoding of polar code P(128,64) over AWGN Channel vs SCL performance.

FIG. 7 FER performance of iterative system for the decoding of polar code P(128,64) over Rayleigh fading channel.

FIG. 8 FER performance of iterative system for the decoding of polar code P(128,64) over Rayleigh fading channel for maximum iteration number 50 and 100.

### DETAILED DESCRIPTION OF THE INVENTION

The novelty of the invention has been described with examples that shall not limit the scope of the invention and which have been intended to only clarify the subject matter of the invention.

A novel method for improving the performance of polar decoders using virtual random channel is presented. The present invention has been described in detail below.

Virtual Random Channel

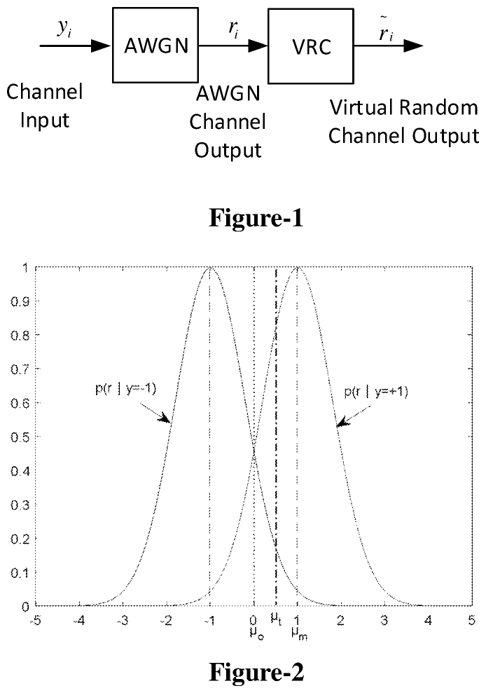

Information bits are polar encoded and transmitted through continuous channel, such as AWGN or Rayleigh, after digital modulation. At the receiver side, before starting to the decoding operation, we consider a virtual random channel (VRC) and pass the received signal through virtual random channel as illustrated in FIG. 1. VRC accepts real numbers as inputs from the continuous channel (AWGN/Rayleigh) and outputs either random or real values (from AWGN/Rayleigh channel). The operation of virtual random channel is described in

$${\tilde{r}}_{i} = \{ \begin{matrix}{n}_{i} , & if - {μ}_{t} \leq {r}_{i} \leq + {μ}_{t} \\ {γ}_{i} , & otherwise\end{matrix}$$

where μₜ is the threshold value, rᵢ is the output of the AWGN and \tilde{r}ᵢ is the output of VRC, and nᵢ is the noise sample having normal distribution, i.e., N(0, 1).

For the determination of threshold, we consider two approaches. In the first approach, threshold value is calculated using the conditional probability density function of the received symbols.

The threshold value calculated using the first approach is constant, and does not change from frame to frame. In the second method, we use an average absolute summation formula for the determination of threshold, and the threshold value calculated using the second method is frame dependent, and may change from frame to frame.

Threshold (μₜ) Determination for AWGN Channel (First Method)

We assume that data bits uᵢ are encoded, and the obtained polar code bits xᵢ are BPSK modulated resulting in yᵢ which are transmitted over AWGN channel. Frame length is N and rᵢ is the received symbol. The conditional probability density function p(rᵢ|yᵢ) given by

$$p ( {r}_{i} \vert {y}_{i} ) = \frac{1}{\sqrt{2 π {σ}^{2}}} exp [ - \frac{{( {r}_{i} - {y}_{i} )}^{2}}{2 {σ}^{2}} ] \qquad \# ( 7 )$$

The graphs of p(rᵢ|yᵢ=−1) and p(rᵢ|yᵢ=1) are depicted in FIG. 2. We define the absolute difference function δ(y) between the two conditional probability density functions as

δ(r)=|p(r|y=1)−p(r|y=−1)| #(8)

The maximum value of δ(r), i.e., δₘₐₓ, can be determined taking the derivative of δ(r) and equating it to zero as in

$$δ ( r ) = \frac{1}{\sqrt{2 π {σ}^{2}}} [ {e}^{\frac{- {( {r}_{i} - 1 )}^{2}}{2 {σ}^{2}}} - {e}^{\frac{- {( {r}_{i} + 1 )}^{2}}{2 {σ}^{2}}} ] \to \qquad \# ( 9 )$$

$${\frac{dδ ( r )}{d r} \vert}_{r = {μ}_{m}} = 0 \to \frac{1}{\sqrt{2 π {σ}^{2}}} [ \frac{1 - r}{{σ}^{2}} {e}^{- {( r - 1 )}^{2} / 2 {σ}^{2}} - \frac{- ( 1 + r )}{{σ}^{2}} {e}^{- {( r + 1 )}^{2} / 2 {σ}^{2}} ] = 0 \qquad \# ( 10 )$$

From (10), we obtain

$$( 1 - {μ}_{𝔪} ) {e}^{\frac{{μ}_{m}}{{σ}^{2}}} = - ( 1 + {μ}_{𝔪} ) {e}^{\frac{- {μ}_{m}}{{σ}^{2}}} \qquad \# ( 11 )$$

which can be solved numerically by using Newton Raphson method [7] and for various values of σ²(0.1→0.9). The value of r at which δ(r) is maximum is found as μₘ≈1.04 which is almost equal to the mean value of p(r|y=1). For the VRC we can choose the threshold level as μₜ=μₘ/4. In Table I, Outputs of VRC for σ=0.631, R=0.5 and μₜ=±0.25 are shown

TABLE I
Outputs of VRC for σ = 0.631, R = 0.5 and μₜ = ±0.25

| | | AWGN | |
|---|---|---|---|
| Input | Encoded | Channel | VRC |
| Symbols | Symbols | Output | Output |
| 1 | 1 | 0.6760 | 0.6760 |
| 1 | 0 | −0.5134 | −0.5134 |
| 1 | 0 | 0.7364 | 0.7364 |
| 1 | 1 | 0.4768 | 0.4768 |
| 0 | 1 | 0.7865 | 0.7865 |
| 1 | 0 | 0.1118 | Random |
| 0 | 0 | −0.0991 | Random |
| 1 | 1 | 1.2775 | 1.2775 |

Threshold (μₜ) Determination Using Absolute Averaging Formula

Let r=[r₁ r₂ . . . r_{N}] be the received signal vector. The threshold value can be estimated using

$${μ}_{t} = \frac{1}{N * log ( N )} * {\sum }_{i = 1}^{N} \vert {r}_{i} \vert$$

where N is the received signal frame length.

In this invention, we consider three threshold intervals [−μₜ μₜ], and the symbols that pass through VRC having signal values falling into the range [−μₜ μₜ] are replaced by randomly generated samples. The output of the VRC is calculated as

$${\tilde{r}}_{i} = \{ \begin{matrix}{n}_{i} , & if - {μ}_{t} \leq {r}_{i} \leq + {μ}_{t} \\ {γ}_{i} , & otherwise\end{matrix}$$

where rᵢ is the input of the VRC, and nᵢ is the noise sample generated using normal distribution with zero mean and unity variance, i.e., N(0,1).

VRCs can be used to improve the performance of SC decoders. In this section, we propose an improved polar decoder structure utilizing two VRCs.

Improved SC Decoder with VRC

Information frame is concatenated with its 8-bit CRC before it is sent to the N-bit polar encoder. Thus, we use N−8 information bits for information sequence. The CRC concatenated information frame has a length of N. We use CRC polynomial

g(x)=x⁸+x⁷+x⁶+x⁴+x²+1

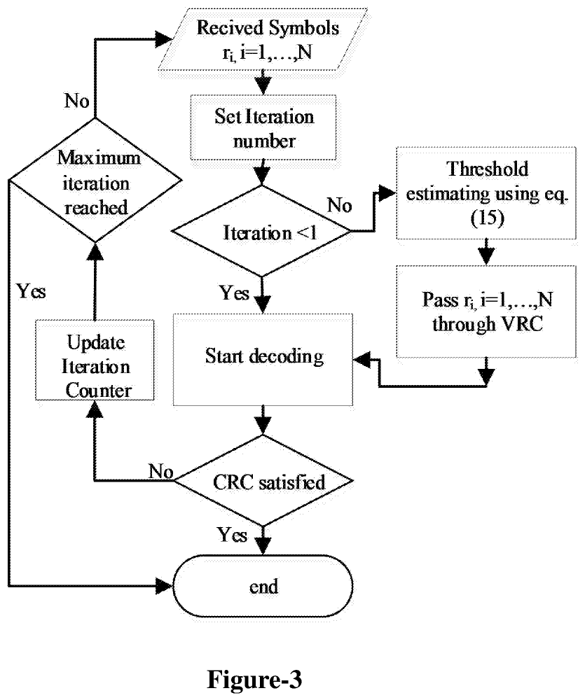

The proposed decoder structure is depicted in FIG. 3 where it is seen that the after estimation of the threshold level, the received signal samples pass through the VRC, and the samples falling into the threshold interval are replaced by noise samples, and those noise samples are randomly generated using zero-mean unity variance Gaussian distribution. The output of the VRC is fed to the successive cancelation (SC) decoder, and when the decoding operation is complete, CRC check is performed. If CRC check is satisfied, then decoding operation halts. Otherwise, new random noise samples are generated and those received samples falling into threshold interval are replaced by new random noise samples, and the output of the VRC is fed to the SC polar decoder and CRC check is performed again, if it is satisfied decoding operation halts, if not, a new iteration is performed using newly generated noise samples. The maximum iteration number is set to a predefined number. As log as CRC is not satisfied, a new iteration is performed with a set of newly generated noise samples, and when the maximum iteration number is reached, decoding operation is stopped even when CRC is not satisfied, and the decisions for the last iteration are considered as the result of the decoding operation.

Simulation Results

We evaluate the performance of the proposed iterative decoding algorithm on a concatenated polar-CRC code with code lengths N=128 and 256 for AWGN and Rayleigh channels with code rate R=0.5. For CRC polynomial, CRC-8 is used. A set of predefined maximum number of iterations (Imax) is used for simulations.

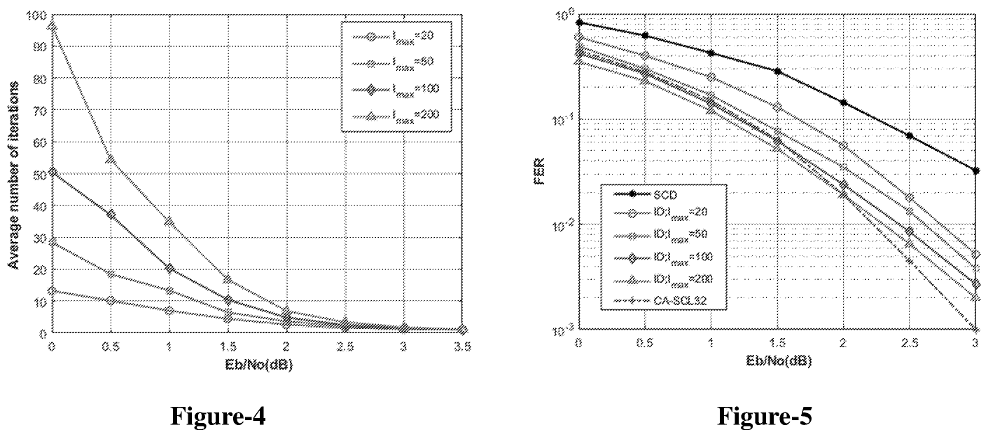

It is seen in FIG. 5 that the proposed iterative decoding techniques over performs CA-SCL32 at low SNR for Imax=50. The same FER performance as CA-SCL32 is achieved at Imax=100, for the same frame length. The computational complexity is provided in terms of the average number of iterations for the proposed algorithm. In FIG. 4, it can be seen that the average number of iterations increases when the decoder operates in the low error-rate region. The average number of iterations depends on the FER of the plain SC decoder as each block failure causes additional iterations over the low reliability received symbols.

In the CRC-aided iterative decoder, the complexity in the low SNR region is high, because the decoder terminates when CRC is satisfied, which is very unlikely due to bad channel conditions.

This work illustrates that CRC-aided iterative decoding (CA-ID) can achieve CRC-aided SCL decoder performance (CA-SCL) for low frame length, when VRC is employed for the received signal. In our experiment, the decoding complexity (and maximum latency) seems to increase drastically in our technique in case of low SNR, it also shown that the increase in complexity is not as dramatic in the moderate and low error rate region.

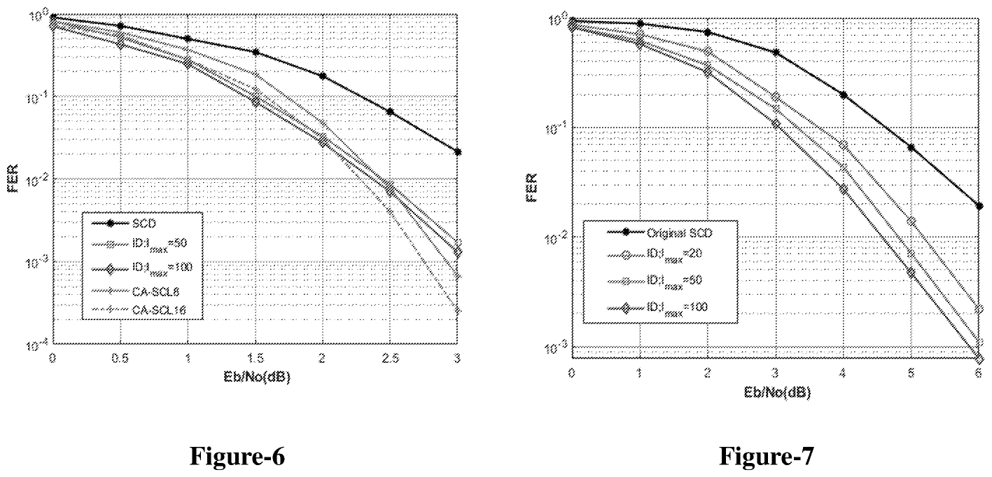

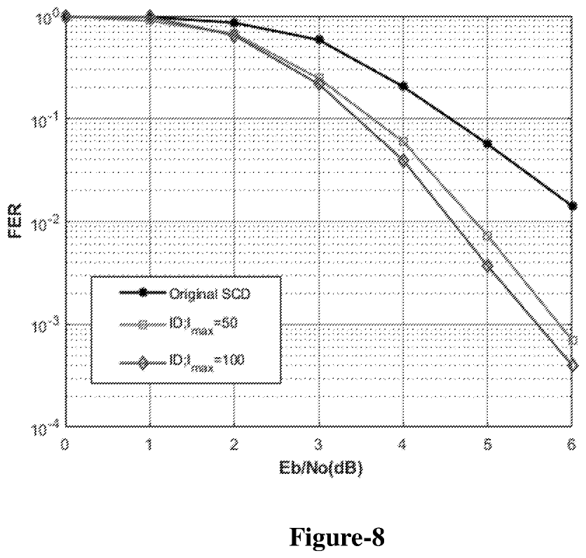

Comprehensively, as shown in FIGS. 5-7, the result shows a significant improvement in polar decoding performance for AWGN and Rayleigh channels, when the iterative decoding is applied over estimated threshold intervals for unreliable channel prediction.

Depending on the detail information above, A method of decoding of polar codes using virtual random channels (VRC) comprising steps of,
A) Concatenating the information frame with its 8-bit CRC before it is sent to the N-bit polar encoder. Using N−8 information bits for information sequence such that the CRC concatenated information frame having a length of N and employing the CRC polynomial

g(x)x⁸+x⁷+x⁶+x⁴+x²+1
B) Calculation of threshold level y which is used by VRC using the received signal vector r=[r₁ r₂ . . . r_{N}] as

$${μ}_{t} = \frac{1}{N * log ( N )} * {\sum }_{i = 1}^{N} \vert {r}_{i} \vert$$

where N is the received signal frame length and also by replacing rᵢ falling into the range [−μₜ μₜ] by nᵢ generated randomly by zero mean unity variance Gaussian random variable generator.
C) Feeding the output of the VRC to successive cancelation decoder, and performing decoding operation,
D) Performing CRC check with CRC polynomial g(x)=x⁸+x⁷+x⁶+x⁴+x²+1 when decoding operation finishes and terminating the decoding operation if CRC is satisfied, otherwise
E) Passing the received signal vector through VRC again, and replacing those received samples falling into threshold interval by new randomly generated noise samples, and feeding the output the VRC to successive cancelation decoder again, and performing decoding operation,
F) Performing CRC check with CRC polynomial g(x)=x⁸+x⁷+x⁶+x⁴+x²+1, and when decoding operation finishes and terminating the decoding operation if CRC is satisfied, otherwise, checking if maximum iteration number is reaches, if it is reached terminate the decoding operation, and accept the decisions of the last iteration as the decoding result. If maximum iteration number is not reached, returning to E) and continuing with the process explained in E).

### REFERENCES

[1] E. Arikan: “Channel Polarization A Method for Constructing Capacity-Achieving Codes for Symmetric Binary-Input Memoryless Channels”, IEEE Trans. Inf. Theory, 2009, 55, (7), pp. 3051-3073.
[2] K. Chen, K. Niu and J. R. Lin: “Improved successive cancellation decoding of polar codes”, IEEE Trans. Commun., 2013, 61, (8), pp. 3100-3107.
[3] K. Daesung, I. Park: “A Fast Successive Cancellation List Decoder for Polar Codes with an Early Stopping Criterion”, IEEE Transactions on Signal Processing, 2018, 66, (18), pp. 4971-4979.
[4] S. A. Hashemi, C. Condo, and W. J: “Simplified Successive Cancellation List Decoding of Polar Codes”, IEEE International Symposium on Information Theory, 2016, pp. 815-819.
[5] B. Li, H. Shen and D. Tse: “An adaptive successive cancellation list decoder for polar codes with cyclic redundancy check”, IEEE Commun. Lett., 2012, (16), 12, pp. 2044-2047.
[6] G. Sarkis, P. Giard, A. Vardy, C. Thibeault, and W. J. Gross: “Fast list Decoders for polar codes”, IEEE J. Sel. Areas Commun., 2016, (34), (2), pp. 318-328.
[7] S. Elsanadily, A. Mahran and O. Elghandour: “Classification-based algorithm for bit-flipping decoding of GLDPC codes over AWGN channels”, IEEE Commun. Lett, 2018, (22), 8, pp. 1520-1523.

1. A method of decoding of polar codes using virtual random channels (VRC) comprising steps of,
Concatenating the information frame with its 8-bit CRC before it is sent to the N-bit polar encoder. Using N−8 information bits for information sequence such that the CRC concatenated information frame having a length of N and employing the CRC polynomial
g(x)x⁸+x⁷+x⁶+x⁴+x²+1
Calculation of threshold level μ which is used by VRC using the received signal vector r=[r₁ r₂ . . . r_{N}] as
$${μ}_{t} = \frac{1}{N * log ( N )} * {\sum }_{i = 1}^{N} \vert {r}_{i} \vert$$
where N is the received signal frame length and replacing rᵢ falling into the range [−μₜ μₜ] by nᵢ generated randomly by zero mean unity variance Gaussian random variable generator
Feeding the output of the VRC to successive cancelation decoder, and performing decoding operation,
Performing CRC check with CRC polynomial g(x)=x⁸+x⁷+x⁶+x⁴+x²+1 when decoding operation finishes and terminating the decoding operation if CRC is satisfied, otherwise,
Passing the received signal vector through VRC again, and replacing those received samples falling into threshold interval by new randomly generated noise samples, and feeding the output of the VRC to successive cancelation decoder again, and performing decoding operation, and after the completion of the decoding operation
Performing CRC check with CRC polynomial g(x)=x⁸+x⁷+x⁶+x⁴+x²+1, and terminating the decoding operation if CRC is satisfied, otherwise, checking if the maximum iteration number is reached or not, if it is reached, terminating the decoding operation, and accepting the decisions of the last iteration as the decoding result. If the maximum iteration number is not reached, returning to E) and continuing with the process as explained in E).
